(19) United States
(12) Patent Application Publication
(10) Pub. No.: US 2024/0241180 A1
(43) Pub. Date: Jul. 18, 2024

(54) BATTERY MANAGEMENT APPARATUS AND BATTERY TESTING SYSTEM INCLUDING THE SAME

(71) Applicant: LG ENERGY SOLUTION, LTD., Seoul (KR)

(72) Inventor: Jung Hoon LEE, Daejeon (KR)

(21) Appl. No.: 18/290,263

(22) PCT Filed: Jul. 27, 2022
(86) PCT No.: PCT/KR2022/011061

§ 371 Date: Nov. 10, 2023

(30) Foreign Application Priority Data
Aug. 13, 2021 (KR) 10-2021-0107250

(51) Int. Cl. G01R 31/367; G01R 31/3842; G01R 31/392

(52) U.S. Cl. CPC G01R 31/367; G01R 31/3842; G01R 31/392

(57) ABSTRACT

A battery management apparatus includes a first controller obtaining state data comprising a measurement value corresponding to a state of a battery. The battery management apparatus also includes a second controller generating prediction data for predicting the state of the battery by applying at least a part of the state data to machine learning. The second controller determines the state of the battery by comparing the prediction data with the state data. The battery management apparatus further includes a communication unit transmitting the state data to a server based on a result of determining the state of the battery.

### CROSS-REFERENCE TO RELATED APPLICATION

This application is a National Phase entry pursuant to 35 U.S.C. 371 of International Application No. PCT/KR2022/011061 filed on Jul. 27, 2022, which claims priority to and the benefit of Korean Patent Application No. 10-2021-0107250 filed in the Korean Intellectual Property Office on Aug. 13, 2021, the entire contents of which are incorporated herein by reference.

### TECHNICAL FIELD

Embodiments disclosed herein relate to a battery management apparatus and a battery testing system including the same.

### BACKGROUND

An electric vehicle is supplied with electricity from outside to charge a battery, and then a motor is driven by a voltage charged in the battery to obtain power. The battery of the electric vehicle may have heat generated therein by chemical reaction occurring in a process of charging and discharging electricity, and the heat may impair performance and lifetime of the battery. Thus, a battery management apparatus (or a battery management system (BMS)) that monitors temperature, voltage, and current of the battery is driven to diagnose the state of the battery.

However, when high-performance GPU or NPU is mounted on the battery management apparatus to precisely analyze the state of the battery in real time, the efficiency of the battery management apparatus is degraded and the cost of the battery management apparatus increases. Moreover, when the entire battery data measured by the battery management apparatus is transmitted to a cloud server for analysis, infra installation cost and communication cost incur and efficiency is degraded in a process of managing and analyzing a lot of data.

The background description provided herein is for the purpose of generally presenting context of the disclosure. Unless otherwise indicated herein, the materials described in this section are not prior art to the claims in this application and are not admitted to be prior art, or suggestions of the prior art, by inclusion in this section.

### SUMMARY

Embodiments disclosed herein aim to provide a battery management apparatus and a battery testing system including the same, in which only data of a battery determined to be in an anomaly situation is precisely analyzed, thereby improving the efficiency of the battery management apparatus and reducing infra installation cost and communication cost.

Technical problems of the embodiments disclosed herein are not limited to the above-described technical problems, and other unmentioned technical problems would be clearly understood by one of ordinary skill in the art from the following description.

A battery management apparatus according to an embodiment disclosed herein includes a first controller that may obtain state data including a measurement value corresponding to a state of a battery, a second controller that may generate prediction data for predicting the state of the battery by applying at least a part of the state data to machine learning, to the second controller may determine the state of the battery by comparing the prediction data with the state data of the battery, and a communication unit that may transmit the state data to a server based on a result of determining the state of the battery.

According to an embodiment, the second controller may be compress, upon determining the battery to be in an anomaly state, the state data obtained for a predetermined time before and after determining the anomaly state.

According to an embodiment, the communication unit may transmit the compressed state data of the battery to the server.

According to an embodiment, the measurement value may include voltage, current, and temperature of the battery, the voltage, current, and temperature of the battery may be measured cumulatively, and the state data may include the measurement value and a state of health (SOH) of the battery, and the SOH of the battery may be calculated based on the measurement value.

According to an embodiment, the prediction data may include a prediction voltage of the battery, and the second controller may predict the prediction voltage of the battery by providing past data included in the state data and measured current and temperature of the battery included in the state data to the machine learning model. The measured current and temperature of the battery may be measured at current time.

According to an embodiment, the second controller may predict the prediction voltage of the battery by providing the state data to the machine learning model. The machine learning model may be based on a long short term memory (LSTM) algorithm.

According to an embodiment, the second controller may generate an anomaly score by applying the state data and the prediction data to an anomaly detection algorithm.

According to an embodiment, the second controller may determine the battery to be in an anomaly state when a percentage of anomaly scores generated for a predetermined time is equal to or greater than a predetermined percentage. The percentage of the anomaly scores may include anomaly values that are equal to or greater than an anomaly threshold value.

A battery testing system according to an embodiment disclosed herein includes a battery management apparatus that may generate prediction data for predicting a state of a battery by applying at least a part of state data including a measurement value resulting from measuring the state of the battery to machine learning. The battery management apparatus may determine the state of the battery by comparing the prediction data with state data of the battery, and the battery management apparatus may transmit the state data to a server based on a result of determining the state of the battery. The battery testing system may include a server that may determine whether the battery is in an anomaly state, based on the state data of the battery.

According to an embodiment, the battery management apparatus may compress, upon determining the battery to be in the anomaly state, the state data obtained for a predetermined time before and after determining the anomaly state, and the battery management apparatus may transmit, upon determining the battery to be in the anomaly state, the compressed state data to the server.

According to an embodiment, the state data may include a measurement value that may include voltage, current, and temperature of the battery. The voltage, current, and temperature of the battery may be measured cumulatively, and the state data may include the measurement value and an SOH of the battery, and the SOH of the battery may be calculated based on the measurement value.

According to an embodiment, the battery management apparatus may predict a prediction voltage of the battery by providing past data included in the state data and measured current and temperature of the battery included in the state data to an LSTM algorithm. The measured current and temperature of the battery may be measured at current time.

According to an embodiment, the battery management apparatus may generate an anomaly score by applying the state data and the prediction data to an anomaly detection algorithm, and to the battery management apparatus may determine the battery to be in the anomaly state when a percentage of anomaly scores generated for a predetermined time is equal to or greater than a predetermined percentage. The percentage of the anomaly scores has anomaly values that are equal to or greater than an anomaly threshold value.

According to an embodiment, the server may extract a false alarm when the battery is erroneously determined to be in the anomaly state in the battery management apparatus.

According to an embodiment, the server may measure the SOH value of the battery and a threshold value of the anomaly detection algorithm, and the server may transmit the SOH value and the threshold value to the battery management apparatus, when a frequency of the false alarm is equal to or greater than a threshold frequency.

According to an embodiment, the battery management apparatus update the LSTM algorithm and the anomaly detection algorithm based on the SOH value and the threshold value, received from the server.

With a battery management apparatus and a battery testing system including the same according to an embodiment disclosed herein, only data of a battery determined to be in an anomaly situation may be precisely analyzed to improve the efficiency of the battery management apparatus and reduce infra installation cost and communication cost.

The effects of the present disclosure are not limited to the effects mentioned above and additional other effects not described above will be clearly understood from the description of the appended claims by those skilled in the art.

### BRIEF DESCRIPTION OF THE DRAWINGS

The accompanying drawings illustrate a preferred embodiment of the present disclosure and together with the foregoing disclosure, serve to provide further understanding of the technical features of the present disclosure, and thus, the present disclosure is not construed as being limited to the drawing.

FIG. 1 illustrates a configuration of a battery pack according to an embodiment disclosed herein.

FIG. 2 is a block diagram illustrating a configuration of a battery management apparatus, according to an embodiment disclosed herein.

FIG. 3 is a view for generally describing a battery management apparatus according to an embodiment disclosed herein.

FIG. 4 is a block diagram illustrating a configuration of a battery testing system according to an embodiment disclosed herein.

FIG. 5 is a flowchart illustrating an operating method of a battery testing system according to an embodiment disclosed herein.

### DETAILED DESCRIPTION

Hereinafter, some embodiments disclosed in this document will be described in detail with reference to the exemplary drawings. In adding reference numerals to components of each drawing, it should be noted that the same components are given the same reference numerals even though they are indicated in different drawings. In addition, in describing the embodiments disclosed in this document, when it is determined that a detailed description of a related known configuration or function interferes with the understanding of an embodiment disclosed in this document, the detailed description thereof will be omitted.

To describe a component of an embodiment disclosed herein, terms such as first, second, A, B, (a), (b), etc., may be used. These terms are used merely for distinguishing one component from another component and do not limit the component to the essence, sequence, order, etc., of the component. The terms used herein, including technical and scientific terms, have the same meanings as terms that are generally understood by those skilled in the art, as long as the terms are not differently defined. Generally, the terms defined in a generally used dictionary should be interpreted as having the same meanings as the contextual meanings of the relevant technology and should not be interpreted as having ideal or exaggerated meanings unless they are clearly defined in the present document.

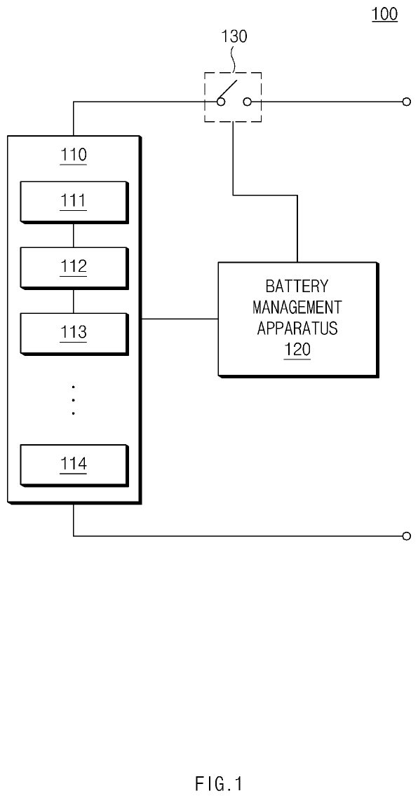

FIG. 1 illustrates a battery pack according to an embodiment disclosed herein.

Referring to FIG. 1, a battery pack 100 according to an embodiment disclosed herein may include a battery module 110, a battery management apparatus 120, and a relay 130.

The battery module 110 may include a first battery cell 111, a second battery cell 112, a third battery cell 113, and a fourth battery cell 114. Although the plurality of battery cells are illustrated as four in FIG. 1, the present disclosure is not limited thereto, and the battery module 110 may include n battery cells (n is a natural number equal to or greater than 2).

The battery module 110 may supply power to a target device (not shown). To this end, the battery module 110 may be electrically connected to the target device. Herein, the target device may include an electrical, electronic, or mechanical device that operates by receiving power from the battery pack 100 including the plurality of battery cells 111, 112, 113, and 114, and the target device may be, for example, an electric vehicle (EV), but is not limited thereto.

The battery cell 111 may be a lithium ion (Li-ion) battery, an Li-ion polymer battery, a nickel-cadmium (Ni—Cd) battery, a nickel hydrogen (Ni-MH) battery, etc., and may not be limited thereto. Meanwhile, although one battery module 110 is illustrated in FIG. 1, the battery module 110 may be configured in plural according to an embodiment.

The battery management apparatus (or a battery management system (BMS)) 120 may manage and/or control a state and/or an operation of the battery module 110. For example, the battery management apparatus 120 may manage and/or control the states and/or operations of the plurality of battery cells 111, 112, 113, and 114 included in the battery module 110. The battery management apparatus 120 may manage charging and/or discharging of the battery module 110.

In addition, the battery management apparatus 120 may monitor a voltage, a current, a temperature, etc., of the battery module 110 and/or each of the plurality of battery cells 111, 112, 113, and 114 included in the battery module 110. A sensor or various measurement modules for monitoring performed by the battery management apparatus 120, which are not shown, may be additionally installed in the battery module 110, a charging/discharging path, any position of the battery module 110, etc. The battery management apparatus 120 may calculate a parameter indicating a state of the battery module 110, e.g., a state of charge (SOC), a state of health (SOH) etc., based on a measurement value such as monitored voltage, current, temperature, etc.

The battery management apparatus 120 may control an operation of the relay 130. For example, the battery management apparatus 120 may short-circuit the relay 130 to supply power to the target device. The battery management apparatus 120 may short-circuit the relay 130 when a charging device is connected to the battery pack 100.

The battery management apparatus 120 may calculate a cell balancing time of each of the plurality of battery cells 111, 112, 113, and 114. Herein, the cell balancing time may be defined as a time required for balancing of the battery cell. For example, the battery management apparatus 120 may calculate a cell balancing time based on an SOC, a battery capacity, and a balancing efficiency of each of the plurality of battery cells 111, 112, 113, and 114.

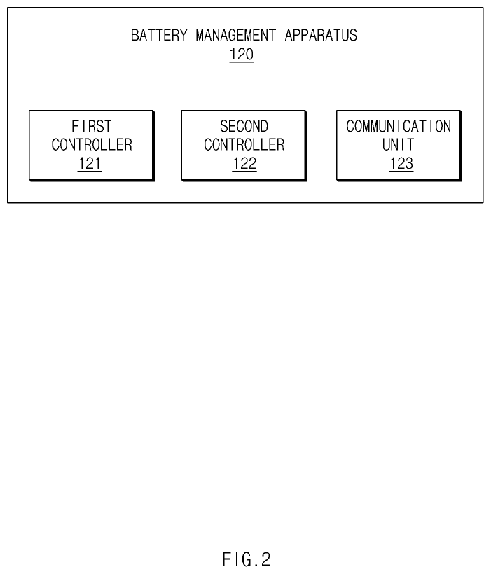

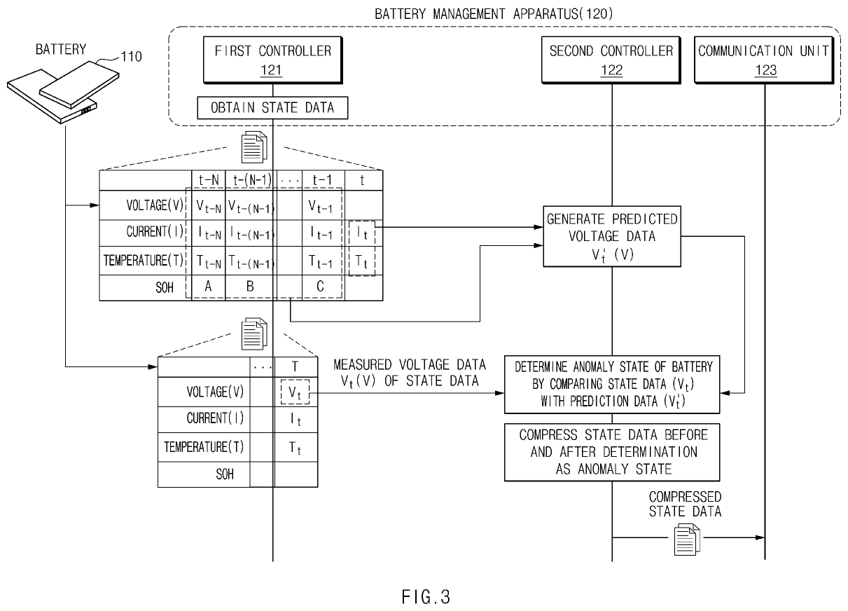

Hereinbelow, referring to FIGS. 2 and 3, a configuration and an operating method the battery management apparatus 120 will be described.

FIG. 2 is a block diagram illustrating a configuration of a battery management apparatus, according to an embodiment disclosed herein. FIG. 3 is a view for generally describing a battery management apparatus according to an embodiment disclosed herein.

Referring to FIG. 2, the battery management apparatus 120 may include a first controller 121, a second controller 122, and a communication unit 123.

In FIG. 2, the battery module 110 may include the plurality of battery cells 111, 112, 113, and 114, but the first battery cell 111 will be described as an example below.

Referring to FIG. 3, the first controller 121 may obtain state data including a measurement value resulting from measuring the state of the first battery cell 111. Herein, the measurement value may include voltage, current, and temperature of the first battery cell 111 measured cumulatively. For example, the state data may include the measurement value including the measured voltage, current, and temperature of the first battery cell 111 and a state of health (SOH) of the first battery cell 111 calculated based on the measurement value.

For example, the first controller 121 may obtain a measurement value resulting from measuring voltage, current, and temperature of the first battery cell 111 from time (t−N) to time (t−1), and obtain an SOH of the first battery cell 111 from the time (t−N) to the time (t−1) based on the measurement value. Herein, N may be defined as a constant value indicating a variation of a variable t indicating time.

For example, the first controller 121 may obtain a voltage V_{t-N}, a current I_{t-N}, and a temperature T_{t-N} of the first battery cell 111 at the time (t−N) to obtain an SOH value of the first battery cell 111 at the time (t−N), and obtain a voltage V_{t-(N-1)}, a current I_{t-(N-1)}, and a temperature T_{t-(N-1)} of the first battery cell 111 at time (t−(N−1)) to obtain an SOH value of the first battery cell 111 at the time (t—(N−1)). That is, the first controller 121 may obtain past state data of the first battery cell 111 from the time (t−N) to the time (t−1).

The first controller 121 may obtain a measurement value of a current Iₜ and a temperature Tₜ of the first battery cell 111 measured at the current time t.

The second controller 122 may apply at least a part of the state data to machine learning to generate prediction data for predicting the state of the first battery cell 111. Herein, the prediction data may include a voltage V′ₜ of the first battery cell 111.

More specifically, the second controller 122 may predict the voltage of the first battery cell 111 by applying past data included in state data and current and temperature of the first battery cell 111 measured at the current time and included in the state data to a machine learning model of a time-series analysis structure. The time series may be defined as an order of arrangement at specific time intervals over time. The machine learning model of the time-series analysis structure may include a long short term memory (LSTM) algorithm. The LSTM algorithm, which is one of artificial neural networks, may be defined as a structure in which a recurrent neural network (RNN) is modified to reflect a long term feature. The LSTM algorithm is mainly applied to problems of time-series data showing a change over time. The LSTM algorithm may predict (n+1)th data for measurement time-series data of an object having a length of n.

The second controller 122 may predict the voltage V′ₜ of the first battery cell 111 at the current time t by applying voltage, current, and temperature and SOH data of the first battery cell 111 from the time (t−N) to the time (t−1) and current data and temperature data of the first battery cell 111 measured at the current time t to the LSTM algorithm. That is, the second controller 122 may generate prediction data for predicting the voltage of the first battery cell 111 at the current time t by applying state data of the first battery cell 111 from the time (t−N) to the time (t−1) to the LSTM algorithm.

The second controller 122 may determine the state of the first battery cell 111 by comparing the prediction data with the state data. More specifically, the second controller 122 may generate an anomaly score by applying the predicted voltage V′ₜ of the first battery cell 111 at the time t and the measured voltage Vₜ of the first battery cell 111 at the time t to an anomaly detection algorithm, thus to analyze an anomaly state of the battery. Herein, the anomaly detection algorithm may be defined as an artificial intelligence model that analyzes an anomaly score of an entity showing a pattern and a feature different from data prescribed as being normal.

That is, the second controller 122 may generate an anomaly score that is a difference between the predicted voltage V′ₜ of the first battery cell 111 at the time t and the measured voltage Vₜ of the first battery cell 111 at the time t.

The second controller 122 may determine that the first battery cell 111 is in the anomaly state, when a rate of anomaly scores equal to or greater than a threshold value among anomaly scores generated for a predetermined time is equal to or greater than a specific rate. That is, when a rate of anomaly scores exceeding the threshold value among anomaly scores, generated for a predetermined time, corresponding to differences between the predicted voltages V′ₜ of the first battery cell 111 and the measured voltages Vₜ of the first battery cell 111, is maintained for several seconds to several tens of seconds, then the second controller 122 may determine the first battery cell 111 to be in the anomaly state.

When the first battery cell 111 is determined to be in the anomaly state, the second controller 122 may compress state data obtained for a predetermined time before and after when the first battery cell 111 is determined to be in the anomaly state.

The communication unit 123 may transmit state data to a server 200 based on a result of determining, by the second controller 122, the state of the first battery cell 111. That is, when the first battery cell 111 is determined to be in the anomaly state, the communication unit 123 may transmit the compressed state data of the first battery cell 111 to the server 200 using an over-the-air (OTA) technique. Herein, the OTA technique, which is one of firmware update schemes, may be defined as a technique for wirelessly updating firmware using Wireless Fidelity (Wi-Fi), etc., without connection to a computer.

As such, with the battery management apparatus 120 and a battery testing system 1000 according to an embodiment disclosed herein, when the battery is determined to be in the anomaly state, battery data is transmitted to the server, thereby improving diagnosis efficiency of the battery management apparatus 120 and preventing unnecessary power supply of the battery management apparatus 120.

The battery management apparatus 120 and the battery testing system 1000 analyze first battery data by using a voltage prediction model designed in the battery management apparatus and transmit the battery data to a server having rich computing resources in the vent of detection of an anomaly phenomenon for precise analysis, thereby precisely analyzing the anomaly phenomenon of the battery and innovatively reducing data transmitted to the server, such that a communication resource may be reduced and storage and computing capabilities of a cloud computer included in the server may be lightened.

The battery management apparatus 120 and the battery testing system 1000 may transmit necessary minimum battery data to the server without a data loss to reduce infrastructure investment cost and network cost of the server.

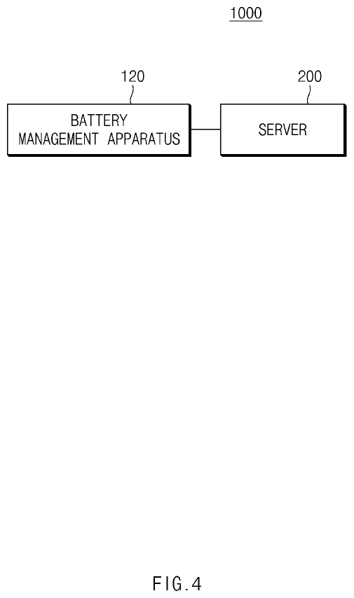

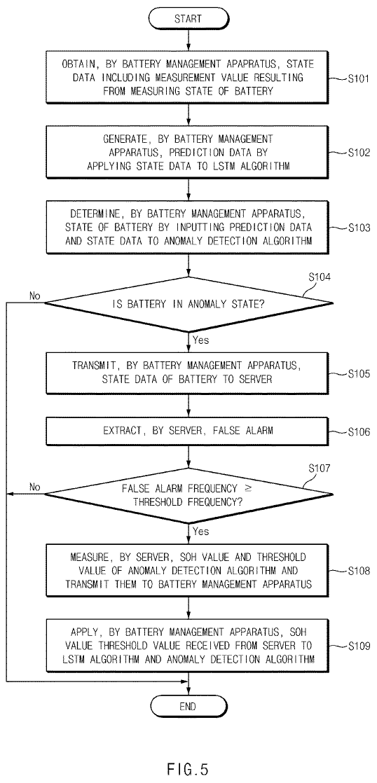

FIG. 4 is a block diagram illustrating a configuration of a battery testing system according to an embodiment disclosed herein. FIG. 5 is a flowchart illustrating an operating method of a battery testing system according to an embodiment disclosed herein.

Hereinbelow, referring to FIGS. 4 and 5, a configuration and an operation of the battery testing system 1000 will be described.

Referring to FIG. 4, the battery testing system 1000 according to an embodiment disclosed herein may include the battery management apparatus 120 and the server 200.

The battery management apparatus 120 may be substantially the same as the battery management apparatus 120 described with reference to FIGS. 1 to 3, and thus will be briefly described to avoid redundant description.

Referring to FIG. 5, an operating method of a battery testing system operation S101 of obtaining, by the battery management apparatus 120, state data including a measurement value resulting from measuring the state of the first battery cell 111, operation S102 of generating, by the battery management apparatus 120, prediction data by applying the state data to an LSTM algorithm, operation S103 of determining, by the battery management apparatus 120, the state of the first battery cell 111 by inputting the prediction data and the state data to an anomaly detection algorithm, operation S104 of determining, by the battery management apparatus 120, whether the first battery cell 111 is in an anomaly state, operation S105 of transmitting, by the battery management apparatus 120, the state data of the first battery cell 111 when the first battery cell 111 is in the anomaly state, operation S106 of extracting, by the server 200, false alarm, operation S107 of determining, by the server 200, whether a frequency of the false alarm is equal to or greater than a threshold frequency, operation S108 of measuring, by the server 200, an SOH value of the first battery cell 111 and the threshold value of the anomaly detection algorithm and transmitting the SOH and the threshold value to the battery management apparatus 120 when the frequency of the false alarm is equal to or greater than the threshold frequency, and operation S109 of applying, by the battery management apparatus 120, the SOH value and the threshold value received from the server 200 to the LSTM algorithm and the anomaly detection algorithm.

Hereinbelow, operations S101 through S109 will be described in detail.

In operation S101, the battery management apparatus 120 may obtain state data including a measurement value resulting from measuring the state of the first battery cell 111. Herein, the state data may include the measurement value including the measured voltage, current, and temperature of the first battery cell 111 and an SOH of the first battery cell 111 calculated based on the measurement value. That is, the battery management apparatus 120 may obtain past state data of the first battery cell 111 from the time (t−N) to the time (t−1). The battery management apparatus 120 may obtain a measurement value of a current and a temperature of the first battery cell 111 measured at the current time t.

In operation S101, the battery management apparatus 120 may apply at least a part of the state data to machine learning to generate prediction data for predicting the state of the first battery cell 111.

For example, in operation S101, the battery management apparatus 120 may predict the voltage V′ₜ of the first battery cell 111 at the current time t by applying voltage, current, and temperature and SOH data of the first battery cell 111 from the time (t−N) to the time (t−1) and current data and temperature data of the first battery cell 111 measured at the current time t to the LSTM algorithm.

In operation S103, the battery management apparatus 120 may determine the state of the first battery cell 111 by comparing the prediction data with the state data. More specifically, the battery management apparatus 120 may generate an anomaly score by applying the predicted voltage V′ₜ of the first battery cell 111 at the time t and the measured voltage Vₜ of the first battery cell 111 at the time t to an anomaly detection algorithm, thus to analyze an anomaly state of the battery.

In operation S104, the battery management apparatus 120 may determine that the first battery cell 111 is in the anomaly state, when a rate of anomaly scores equal to or greater than a threshold value among anomaly scores generated for a predetermined time is equal to or greater than a specific rate.

In operation S105, when the first battery cell 111 is determined to be in the anomaly state, the battery management apparatus 120 may compress state data obtained for a predetermined time before and after when the first battery cell 111 is determined to be in the anomaly state, and transmit the compressed state data to the server 200.

The server 200 may be defined as a determining apparatus that receives the state data of the first battery cell 111 and determines whether the first battery cell 111 is defective. The server 200 may include, for example, a cloud computing technique.

The server 200 may include an artificial intelligence model that extracts false alarm corresponding to a case where the first battery cell 111 is determined to be in the anomaly state based on the state data of the first battery cell 111 determined by the battery management apparatus 120 even though the first battery cell 111 is not actually in the anomaly state.

In operation S106, when the battery management apparatus 120 compresses the state data of the first battery cell 111 obtained for a predetermined time before and after when the battery management apparatus 120 is determined in the anomaly state, and transmits the compressed state data to the server 200, the server 200 may receive the compressed state data transmitted from the battery management apparatus 120.

In operation S106, the server 200 may analyze the compressed data received from the battery management apparatus 120, that is, the state data obtained for the predetermined time before and after the determination as the anomaly state to extract false alarm corresponding to the case where the first battery cell 111 is determined to be in the anomaly state even though the first battery cell 111 is not actually in the anomaly state.

In operation S107, the server 200 may determine whether a frequency of the false alarm is equal to or greater than a threshold frequency.

In operation S108, when the frequency of the false alarm is equal to or greater than the threshold frequency, the server 200 may recalculate an SOH value of the first battery cell 111 included in the battery management apparatus 120 and reset a threshold value of an anomaly detection algorithm for transmission to the battery management apparatus 120.

That is, in operation S108, the server 200 may analyze a cause for occurrence of the false alarm of the first battery cell 111 as the SOH value of the first battery cell 111 and the threshold value of the anomaly detection algorithm, input to the LSTM algorithm of the battery management apparatus 120.

The LSTM algorithm of the battery management apparatus 120 may receive, as past data included in the state data of the first battery cell 111, a measurement value resulting from measuring voltage, current, and temperature of the first battery cell 111 and an SOH value of the first battery cell 111 based on the measurement value. Thus, when an error occurs in a process of calculating, by the battery management apparatus 120, the voltage, current, and temperature of the first battery cell 111 and the SOH value of the first battery cell 111, an error may occur in the LSTM algorithm and this error may cause false alarm of the battery testing system 1000. Thus, the server 200 may recalculate the SOH value of the first battery cell 111 input to the battery management apparatus 120 and transmit the recalculated SOH value to the battery management apparatus 120.

In operation S108, the server 200 may analyze a cause for occurrence of the false alarm of the first battery cell 111 as the threshold value of the anomaly detection algorithm of the battery management apparatus 120.

The battery management apparatus 120 may generate an anomaly score that is a difference between the predicted voltage V′ₜ of the first battery cell 111 at the time t and the measured voltage Vₜ of the first battery cell 111 at the time t by using the anomaly detection algorithm, and determine the first battery cell 111 to be in the anomaly state when a rate of anomaly scores greater than a threshold value among generated anomaly scores is greater than a specific rate. Thus, when the threshold value for determining, by the battery management apparatus 120, the anomaly score as an abnormal value is not appropriate, an error may occur for the battery management apparatus 120 to determine the anomaly state of the first battery cell 111, and this error may cause false alarm of the battery testing system 1000. Thus, the server 200 may reset the threshold value of the anomaly detection algorithm input to the battery management apparatus 120 and transmit the reset threshold value to the battery management apparatus 120.

In operation S109, when the battery management apparatus 120 receives the SOH value of the first battery cell 111 and the threshold value of the anomaly detection algorithm from the server 200, the battery management apparatus 120 may update the LSTM algorithm and the anomaly detection algorithm.

The above description is merely illustrative of the technical idea of the present disclosure, and various modifications and variations will be possible without departing from the essential characteristics of the present disclosure by those of ordinary skill in the art to which the present disclosure pertains.

Therefore, the embodiments disclosed in the present disclosure are intended for description rather than limitation of the technical spirit of the present disclosure and the scope of the technical spirit of the present disclosure is not limited by these embodiments. The protection scope of the present disclosure should be interpreted by the following claims, and all technical spirits within the same range should be understood to be included in the range of the present disclosure.

1. A battery management apparatus comprising:
a first controller obtaining state data comprising a measurement value corresponding to a state of a battery;
a second controller generating prediction data for predicting the state of the battery by applying at least a part of the state data to machine learning,
wherein the second controller determines the state of the battery by comparing the prediction data with the state data; and
a communication unit transmitting the state data to a server based on a result of determining the state of the battery.

2. The battery management apparatus of claim 1, wherein the second controller compresses, upon determining the battery to be in an anomaly state, the state data obtained for a predetermined time before and after determining the anomaly state.

3. The battery management apparatus of claim 2, wherein the communication unit transmits the compressed state data of the battery to the server.

4. The battery management apparatus of claim 1, wherein the measurement value comprises voltage, current, and temperature of the battery,
wherein the voltage, current, and temperature of the battery are measured cumulatively, and
wherein the state data comprises the measurement value and a state of health (SOH) of the battery, and
wherein the SOH of the battery is calculated based on the measurement value.

5. The battery management apparatus of claim 4, wherein the prediction data comprises a prediction voltage of the battery,
wherein the second controller predicts the prediction voltage of the battery by providing past data included in the state data and measured current and temperature of the battery included in the state data to a machine learning model, and
wherein the measured current and temperature of the battery are measured at current time.

6. The battery management apparatus of claim 5, wherein the second controller predicts the prediction voltage of the battery by providing the state data to the machine learning model, and
wherein the machine learning model is based on a long short term memory (LSTM) algorithm.

7. The battery management apparatus of claim 4, wherein the second controller generates an anomaly score by applying the state data and the prediction data to an anomaly detection algorithm.

8. The battery management apparatus of claim 7, wherein the second controller determines the battery to be in an anomaly state when a percentage of anomaly scores generated for a predetermined time is equal to or greater than a predetermined percentage, and
Wherein the percentage of the anomaly scores has anomaly values that are equal to or greater than an anomaly threshold value.

9. A battery testing system comprising:
a battery management apparatus generating prediction data for predicting a state of a battery by applying at least a part of state data comprising a measurement value resulting from measuring the state of the battery to machine learning,
wherein the battery management apparatus determines the state of the battery by comparing the prediction data with state data of the battery, and
wherein the battery management apparatus transmits the state data to a server based on a result of determining the state of the battery; and
a server determining whether the battery is in an anomaly state based on the state data of the battery.

10. The battery testing system of claim 9, wherein the battery management apparatus compresses, upon determining the battery to be in the anomaly state, the state data obtained for a predetermined time before and after determining the anomaly state, and
wherein, the battery management apparatus transmits, upon determining the battery to be in the anomaly state, the compressed state data to the server.

11. The battery testing system of claim 9, wherein the state data comprises a measurement value comprising voltage, current, and temperature of the battery,
wherein the voltage, current, and temperature of the battery are measured cumulatively, and
wherein the state data comprises the measurement value and a state of health (SOH) of the battery, and
wherein the SOH of the battery is calculated based on the measurement value.

12. The battery testing system of claim 11, wherein the battery management apparatus predicts a prediction voltage of the battery by providing past data included in the state data and measured current and temperature of the battery included in the state data to a long short term memory (LSTM) algorithm,
wherein the measured current and temperature of the battery are measured at current time.

13. The battery testing system of claim 11, wherein the battery management apparatus generates an anomaly score by applying the state data and the prediction data to an anomaly detection algorithm, and
wherein the battery management apparatus determines the battery to be in the anomaly state when a percentage of anomaly scores generated for a predetermined time is equal to or greater than a predetermined percentage, and
wherein the percentage of the anomaly scores has anomaly values that are equal to or greater than an anomaly threshold value.

14. The battery testing system of claim 13, wherein the server extracts a false alarm when the battery is erroneously determined to be in the anomaly state in the battery management apparatus.

15. The battery testing system of claim 14, wherein the server measures the SOH value of the battery and a threshold value of the anomaly detection algorithm, and
wherein the server transmits the SOH value and the threshold value to the battery management apparatus when a frequency of the false alarm is equal to or greater than a threshold frequency.

16. The battery testing system of claim 15, wherein the battery management apparatus updates the LSTM algorithm and the anomaly detection algorithm based on the SOH value and the threshold value, received from the server.
